(19) United States
(12) Patent Application Publication
(10) Pub. No.: US 2017/0314850 A1
(43) Pub. Date: Nov. 2, 2017

(54) Refrigerator Appliance and Heater for Preventing Condensation

(71) Applicant: General Electric Company, Schenectady, NY (US)

(72) Inventors: Madan Gopal Reddy Pathapati, Louisville, KY (US); Stephanos Kyriacou, Louisville, KY (US); Jivko Ognianov Djerekarov, Louisville, KY (US)

(21) Appl. No.: 15/140,525

(22) Filed: Apr. 28, 2016

(51) Int. Cl. F25D 29/00; F25B 13/00; H05K 1/02

(52) U.S. Cl. CPC F25D 29/005; H05K 1/0212; F25B 13/00; F25B 2500/14

(57) ABSTRACT

An appliance is provided that may include a cabinet, a board enclosure, an electronic circuit board, and a heating conduit. The cabinet may have an outer surface and an inner surface defining an enclosed chilled chamber. The board enclosure may define a protective cavity and be attached to the outer surface of the cabinet. The electronic circuit board may be attached to the board enclosure within the protective cavity. The heating conduit may enclose a circulating fluid. The heating conduit may be positioned in conductive heating engagement with a portion of the board enclosure to supply heat to the protective cavity.

### FIELD OF THE INVENTION

The present subject matter relates generally to appliances, and more particularly to systems for preventing condensation at a portion of an appliance.

### BACKGROUND OF THE INVENTION

Refrigerators generally include a cabinet that defines at least one chilled chamber. An electronic device, such as a circuit board, is often mounted to the cabinet, e.g., to control a portion of the appliance. Although the electronic device may be mounted outside of the chilled chamber, conductive or convective heat transfer from various portions of the appliance may cause the area around the electronic device to be substantially cooled. Such cooling may cause ambient water vapor to condense or accumulate on or near the electronic device. Together or alone, the reduced heat or condensed vapor may interfere with performance of the electronic device.

Some existing refrigerator appliances may include a separate heater, such as a resistive electric heater, positioned outside of the chilled chamber to increase the heat at a select portion of the cabinet, e.g., to reduce frost. However, such systems generally complicate the appliance and require greater amounts of electricity or power to operate. That power must be selectively applied and controlled. Moreover, existing electric heaters may be unsuitable for use on or near an electronic device. If not properly configured or controlled, heat that is generated by an electric heater near a separate electronic device may result in harm or damage to the electronic device.

Accordingly, a refrigerator appliance with features for controlling the temperature and/or condensation outside of refrigerator appliance would be useful. In addition, it may be desirable to provide such features without significantly increasing the power consumption of the appliance or increasing the risk of harm to an electronic device.

### BRIEF DESCRIPTION OF THE INVENTION

Aspects and advantages of the invention will be set forth in part in the following description, or may be obvious from the description, or may be learned through practice of the invention.

In one aspect of the present disclosure, an appliance is provided. The appliance may include a cabinet, a board enclosure, an electronic circuit board, and a heating conduit. The cabinet may have an outer surface and an inner surface defining an enclosed chilled chamber. The board enclosure may define a protective cavity and be attached to the outer surface of the cabinet. The electronic circuit board may be attached to the board enclosure within the protective cavity. The heating conduit may enclose a circulating fluid. The heating conduit may be positioned in conductive heating engagement with a portion of the board enclosure to supply heat to the protective cavity.

In another aspect of the present disclosure, an appliance is provided. The appliance may include a cabinet, a board enclosure, an electronic circuit board, and a sealed refrigeration loop. The cabinet may have an outer surface and an inner surface defining an enclosed chilled chamber. The board enclosure may define a protective cavity and be attached to the outer surface of the cabinet. The electronic circuit board may be attached to the board enclosure within the protective cavity. The sealed refrigeration loop may include a compressor, a condenser, a heating conduit, and an expansion valve. The compressor may be operable to generate a flow of refrigerant. The condenser may be disposed downstream of the compressor such that the condenser receives the flow of refrigerant from the compressor during operation of the compressor. The heating conduit may be disposed downstream of the condenser in conductive heating engagement with a portion of the board enclosure to supply heat to the protective cavity. The expansion device may be disposed downstream of the heating conduit.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure of the present invention, including the best mode thereof, directed to one of ordinary skill in the art, is set forth in the specification, which makes reference to the appended figures.

FIG. 1 provides a front view of a refrigerator appliance according to an exemplary embodiment of the present disclosure.

FIG. 2 provides a schematic view of certain components of the exemplary embodiment of FIG. 1.

FIG. 3 provides a front view of certain components of an exemplary embodiment of the present disclosure, including an exemplary heating assembly.

FIG. 4 provides a front magnified view of certain components of the exemplary heating assembly of FIG. 3.

FIG. 5 provides a perspective view of the exemplary heating assembly of FIG. 3.

FIG. 6 provides an exploded perspective view of the exemplary heating assembly of FIG. 3.

FIG. 7 provides a cross sectional bottom view of the exemplary heating assembly of FIG. 3.

### DETAILED DESCRIPTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

In some aspects of the present disclosure, a refrigerator appliance is provided with a cabinet that defines a chilled chamber. A circuit board for controlling the appliance is mounted to the cabinet within an enclosure outside of the chilled chamber. A heating conduit is placed in contact with the enclosure and heats a portion of the enclosure by flowing a circulating fluid through the heating conduit from a sealed system compressor and condenser.

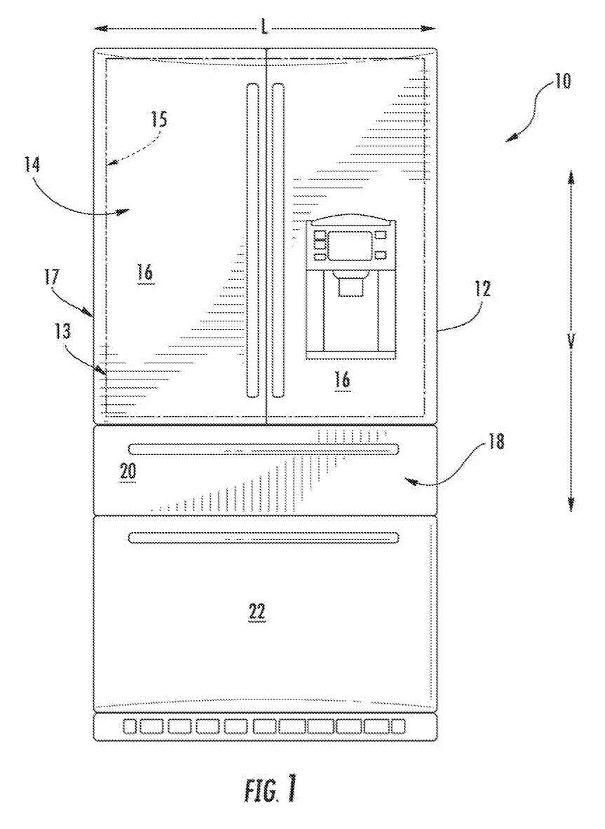

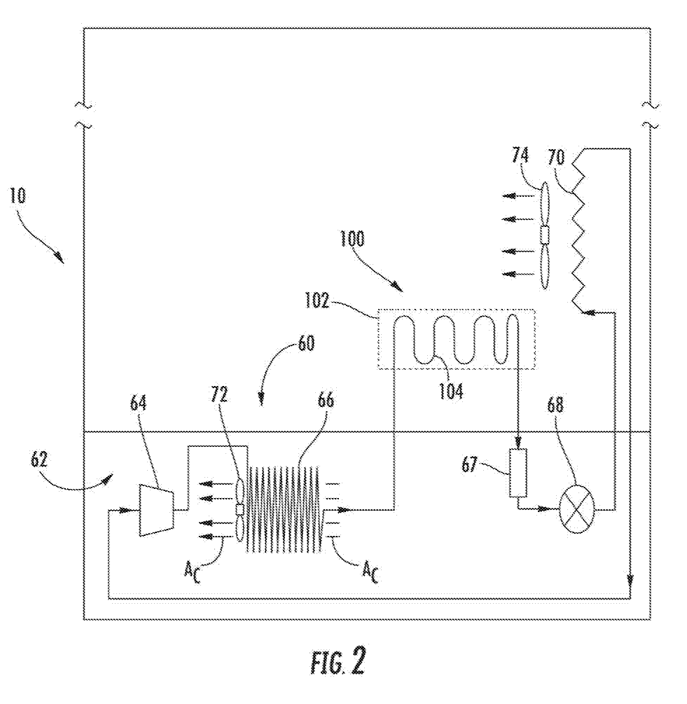

FIG. 1 depicts a refrigerator appliance 10 that incorporates a sealed refrigeration system 60 (FIG. 2). It should be appreciated that the term “refrigerator appliance” is used in a generic sense herein to encompass any manner of refrigeration appliance, such as a freezer, refrigerator/freezer combination, and any style or model of conventional refrigerator. In addition, it should be understood that the present subject matter is not limited to use in appliances. Thus, the present subject matter may be used for any other suitable purpose, such as vapor compression within air conditioning units or air compression within air compressors.

In the illustrated exemplary embodiment shown in FIG. 1, the refrigerator appliance 10 is depicted as an upright refrigerator having a cabinet or casing 12 having an outer surface 13 and an inner surface 15 defining an enclosed chilled chamber. In some embodiments, each of outer surface 13 and inner surface 15 is at least partially enclosed within an external shell 17. Optionally, the chilled chamber includes one or more upper fresh-food compartments 14 and one or more lower freezer compartments 18. Generally, cabinet 12 further defines a vertical direction V, a lateral direction L, and a transverse direction (not pictured). The vertical direction V, lateral direction L, and transverse direction are all mutually perpendicular and form an orthogonal direction system.

In certain embodiments, refrigerator appliance 10 includes upper fresh-food compartments 14 having doors 16 and lower freezer compartment 18 having upper drawer 20 and lower drawer 22. The drawers 20 and 22 are “pull-out” drawers in that they can be manually moved into and out of the freezer compartment 18, e.g., in the transverse direction, on suitable slide mechanisms.

FIG. 2 is a schematic view of certain components of refrigerator appliance 10, including a sealed refrigeration system 60 of refrigerator appliance 10. A machinery compartment 62 contains components for executing a known vapor compression cycle for cooling air. The components include a compressor 64, a condenser 66, a fluid filter 67, an expansion device 68, and an evaporator 70 connected in series and charged with an enclosed circulating fluid, such as a suitable refrigerant, e.g., HFC-134a, R-600a, etc. As will be understood by those skilled in the art, refrigeration system 60 may include additional components, e.g., at least one additional evaporator, compressor, expansion device, and/or condenser. As an example, refrigeration system 60 may include two evaporators.

Within refrigeration system 60, refrigerant flows into compressor 64, which operates to increase the pressure of the refrigerant. This compression of the refrigerant raises its temperature, which is lowered by passing the refrigerant through condenser 66. Within condenser 66, heat exchange with ambient air takes place so as to cool the refrigerant. A condenser fan 72 is used to pull air across condenser 66, as illustrated by arrows A_{C}, so as to provide forced convection for a more rapid and efficient heat exchange between the refrigerant within condenser 66 and the ambient air. Thus, as will be understood by those skilled in the art, increasing air flow across condenser 66 can, e.g., increase the efficiency of condenser 66 by improving cooling of the refrigerant contained therein.

An expansion device (e.g., a valve, capillary tube, or other restriction device) 68 receives refrigerant from condenser 66. Optionally, fluid filter 67 may condition refrigerant by drawing excessive or excess moisture from the refrigerant before it is received by expansion device 68. From expansion device 68, the refrigerant enters evaporator 70. Upon exiting expansion device 68 and entering evaporator 70, the refrigerant drops in pressure. Due to the pressure drop and/or phase change of the refrigerant, evaporator 70 is cool relative to compartments 14 and 18 of refrigerator appliance 10. As such, cooled air is produced and refrigerates compartments 14 and 18 of refrigerator appliance 10. Thus, evaporator 70 is a type of heat exchanger which transfers heat from air passing over evaporator 70 to refrigerant flowing through evaporator 70. An evaporator fan 74 is used to pull air across evaporator 70 and circulated air within compartments 14 and 18 of refrigerator appliance 10.

Collectively, the vapor compression cycle components in a refrigeration circuit, associated fans, and associated compartments are sometimes referred to as a sealed refrigeration system operable to force cold air through compartments 14, 18 (FIG. 1). The refrigeration system 60 depicted in FIG. 2 is provided by way of example only. Thus, it is within the scope of the present subject matter for other configurations of the refrigeration system to be used as well.

As shown, exemplary embodiments further include a heating assembly 100 in fluid communication with or fluid series within sealed refrigeration system 60. In exemplary embodiments similar to FIG. 2, heating assembly 100 includes a heating conduit 104 disposed in fluid series downstream from compressor 64 between condenser 66 and fluid filter 67 or expansion device 70. Generally, heating conduit 104 is formed from one or more suitable material. For instance, in exemplary embodiments, heating conduit 104 is formed at least partially by one or more metal, such as copper, aluminum, or steel.

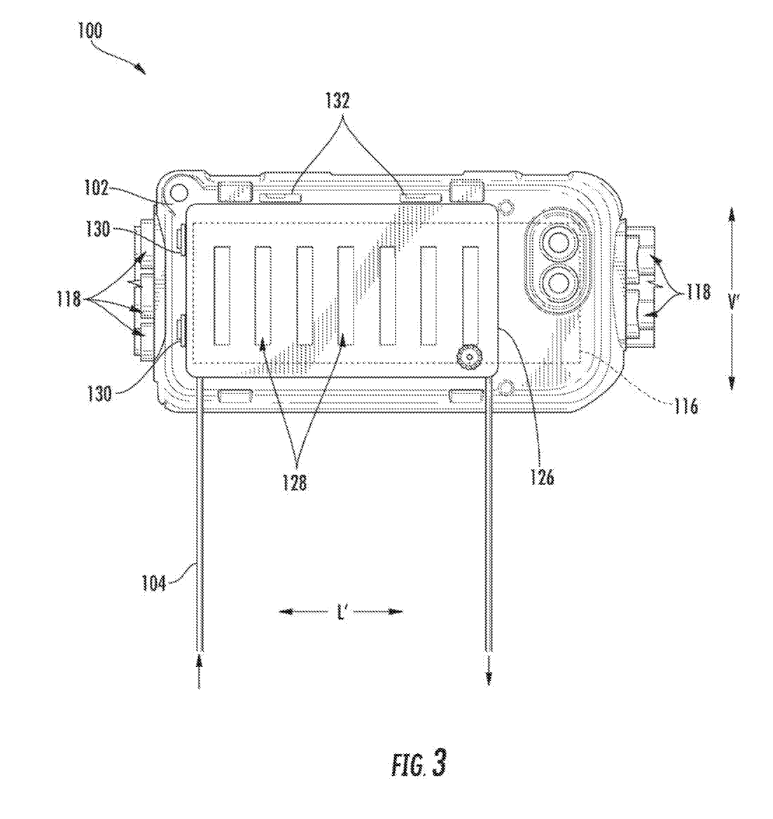

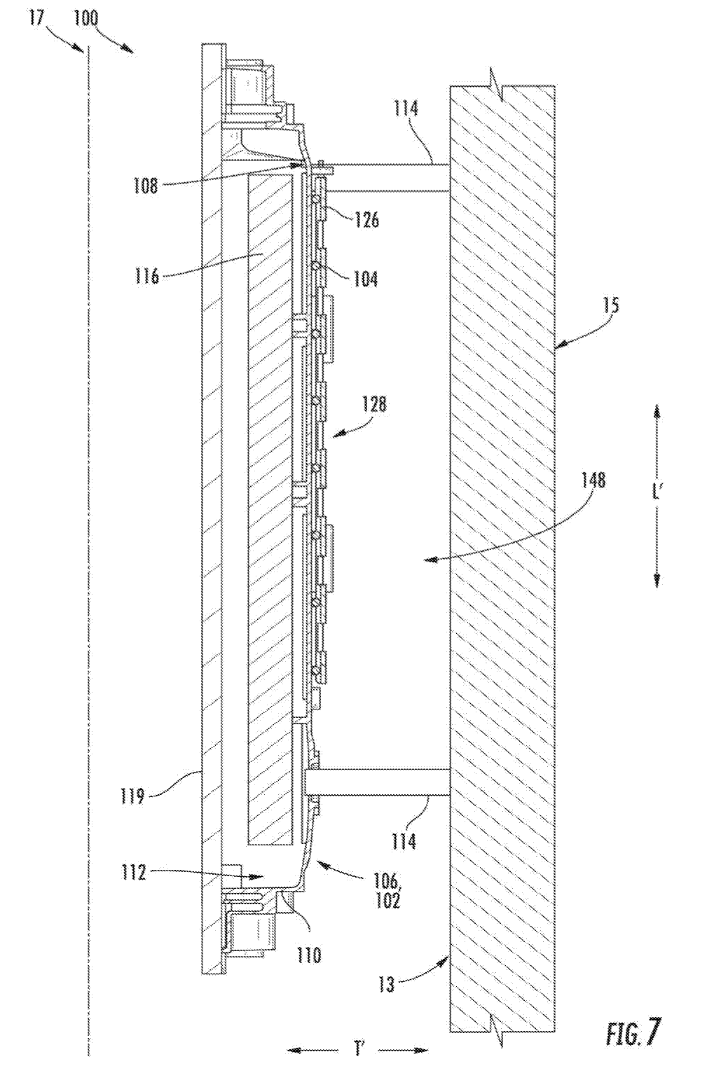

Turning to FIGS. 3 through 7, exemplary embodiments of heating assembly 100 are provided. Generally, heating assembly 100 includes a board enclosure 102 that defines a vertical direction V′, a lateral direction L′, and a transverse direction T′. The vertical direction V′, lateral direction L′, and transverse direction T′ are all mutually perpendicular and form an orthogonal direction system. When assembled, it is understood that the orthogonal direction system of board enclosure 102 is parallel to the orthogonal direction system of cabinet 12 (see FIG. 1).

As shown, board enclosure 102 is mounted to a portion of cabinet 12. Specifically, board enclosure 102 is attached to outer surface 13 of cabinet 12. In some embodiments, board enclosure 102 includes a pair of oppositely-directed faces, e.g., a cabinet-side face 106 and a cavity-side face 108. When board enclosure 102 is mounted to cabinet 12, cabinet-side face 106 is directed toward outer surface 13 of cabinet 12, while cavity-side face 108 is directed in the opposite direction, away from cabinet 12. One or more sidewalls 110 may extend from cavity-side face 108, e.g., in the transverse direction T′. Together, cavity-side face 108 and sidewalls 110 at least partially define a protective cavity 112. In some embodiments, protective cavity 112 is formed as a partially enclosed recess. Sidewalls 110 may generally bound protective cavity 112, e.g., at lateral and vertical extremes.

In optional embodiments, one or more selective attachment members 114 are provided to secure board enclosure 102 to cabinet 12. For example, one or more screws, bolts, clips, brackets, etc. may be positioned on or through board enclosure 102 and cabinet 12. Additionally or alternatively, adhesive may secure board enclosure 102 to cabinet 12.

In exemplary embodiments, an electronic circuit board 116 is attached to board enclosure 102. In some embodiments, electronic circuit board 116 is mounted and guarded within protective cavity 112. Sidewalls 110 cover a portion of electronic circuit board 116, e.g., in the transverse direction T′ and vertical direction V′, while cavity-side face 108 covers another portion, e.g., in the lateral direction L′. In turn, cavity-side face 108 is positioned between outer surface 13 and electronic circuit board 116. Optionally, a board lid 119 is disposed over cavity-side face 108 to cover and fully enclose electronic circuit board 116 within protective cavity 112.

Generally, electronic circuit board 116 is configured to control an operation appliance 10 (see FIG. 2). For example, electronic circuit board 116 may be configured to initiate functional operations of an appliance based on a stored program, input received from an input selector (not pictured), and/or inputs received from various sensors (not pictured) disposed within cabinet 12. In some embodiments, electronic circuit board 116 includes one or more memory devices and one or more microprocessors, such as general or special purpose microprocessors operable to execute programming instructions or micro-control code associated with operations of appliance 10 (see FIG. 1). The memory may represent random access memory such as DRAM, or read only memory such as ROM or FLASH. In one embodiment, the processor executes programming instructions stored in memory. The memory may be a separate component from the processor or may be included onboard within the processor.

When assembled, electronic circuit board 116 is generally configured in operable communication, e.g., electrically connected to, another portion of appliance 10 to control one or more operation thereof. For instance, in optional embodiments, electronic circuit board 116 is electrically connected to sealed refrigeration system 60 (see FIG. 2), e.g., at compressor 64. Electronic circuit board 116 may be configured to control activation and/or operation of sealed refrigeration system 60 (see FIG. 2). In some such embodiments, one or more wiring passages 118 are defined through board enclosure 102, permitting electrical wiring to be directed into board enclosure 102. For instance, in exemplary embodiments, a plurality of wiring passages 118 is defined through sidewalls 110 in the lateral direction L′. Electrical wiring disposed through wiring passages 118 may operably connect electronic circuit board 116 to another portion of appliance 10 (see FIG. 1).

In some embodiments, heating conduit 104 engages at least a portion of a board enclosure 102. For instance, as shown, heating conduit 104 may directly contact board enclosure 102. Heating conduit 104 may be positioned on board enclosure 102 in engagement, e.g., conductive engagement, therewith. In exemplary embodiments, heating conduit 104 is attached to the board enclosure 102 between a chilled chamber 14, 18 (see FIG. 1) and electronic circuit board 116. For example, heating conduit 104 may be attached to cabinet-side face 106 such that heating conduit 104 faces the outer surface 13 of cabinet 12. Optionally, heating conduit 104 may directly contact board enclosure 102 at cabinet-side face 106 and conduct heat from the circulating fluid to board enclosure 102. During operation of sealed refrigeration system 60 (see FIG. 2), refrigerant flowed through heating conduit 104 conductively heats board enclosure 102. Through board enclosure 102, heat may then be transmitted to protective cavity 112. Moreover, once it reaches protective cavity 112, heat from heating conduit 104 may increase the temperature of air surrounding the electronic circuit board 116. In exemplary embodiments, the heat provided at board enclosure 102, e.g., temperature of the circulating fluid, is predetermined according to a typical or average dew point of ambient air within protective cavity 112.

In some embodiments, heating conduit 104 defines a plurality of conduit passes 120 positioned on board enclosure 102. Each conduit pass 120 extends along a portion of board enclosure 102 before being gradually redirected in an opposite direction. Generally, each conduit pass 120 includes at least one bend 122 redirecting heating conduit 104, and thus, the flow of refrigerant therethrough. In exemplary embodiments, heating conduit 104 forms a plurality of S-shaped bends across cabinet-side face 106 of board enclosure 102. Advantageously, the number of conduit passes 120 and/or surface area of heating conduit 104 positioned on board enclosure 102 may be tuned according to a typical or average temperature of refrigerant through heating conduit 104 at board enclosure 102 and/or a typical or average dew point of ambient air within protective cavity 112.

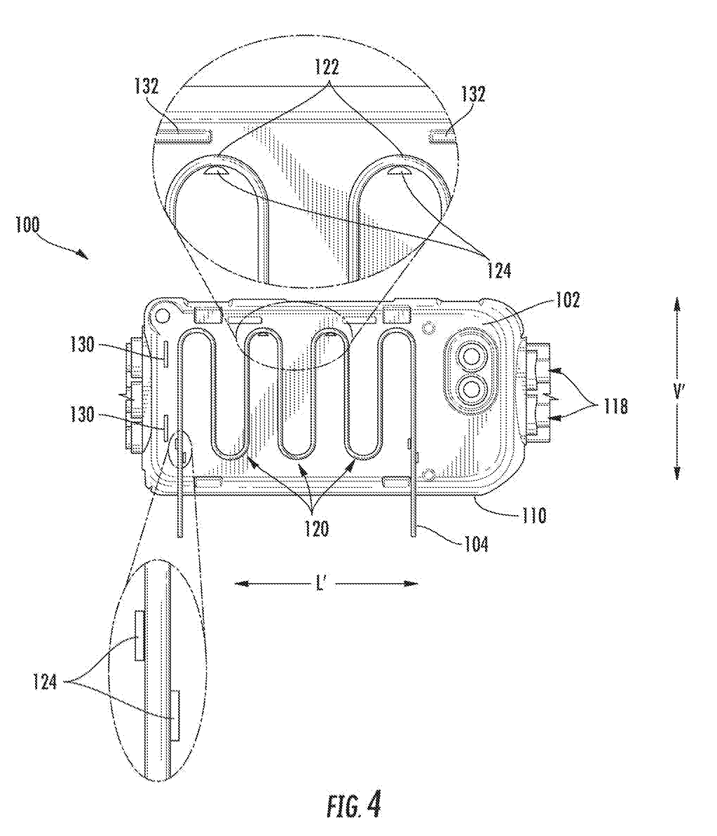

As illustrated in FIG. 4, in exemplary embodiments, one or more integral tabs 124 extend from board enclosure 102 in further contact with heating conduit 104. As shown, integral tabs 124 extend from cabinet-side face 106 in the transverse direction T′. Optionally, one or more integral tabs 124 may configured as a pair bounding the heating conduit 104, e.g., in the lateral direction L′. Each pair of integral tabs 124 may frictionally engage heating conduit 104, holding heating conduit 104 against board enclosure 102. Additionally or alternatively, one or more integral tabs 124 are positioned against heating conduit 104 at a bend 122 of a respective conduit pass 120. In some such embodiments, integral tabs 124 guide heating conduit 104 across board enclosure 102, e.g., at cabinet-side face 106.

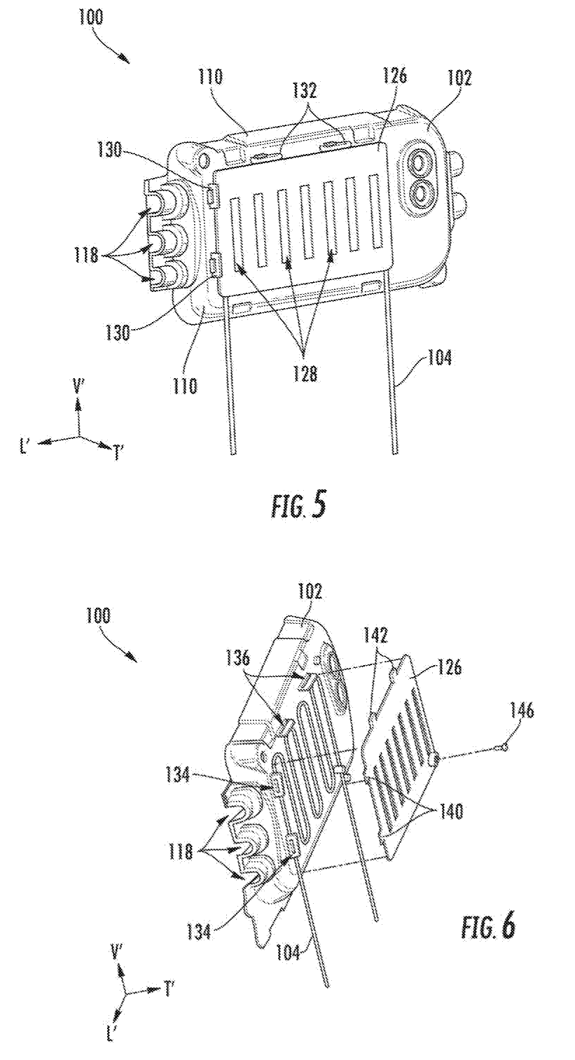

Turning to FIGS. 5 through 7, a retention plate 126 is positioned across the heating conduit 104. As shown, retention plate 126 extends over heating conduit 104 between outer surface 13 of cabinet 12 and the heating conduit 104. When assembled, heating conduit 104 is held against cabinet-side face 106 of board enclosure 102 between retention plate 126 and electronic circuit board 116.

One or more apertures 128 may be defined in retention plate 126. Particularly, a plurality of apertures 128 may be defined as extending through retention plate 126. For instance, each aperture 128 may extend fully through retention plate 126, e.g., in the transverse direction T′. Moreover, each aperture 128 may be directed toward the outer surface 13 of the cabinet 12 and cabinet-side face 106 of board enclosure 102. In certain exemplary embodiments, each aperture 128 is spaced apart from the other apertures 128, e.g., in the lateral direction L′. Optionally, each aperture 128 is defined between a conduit pass 120 of heating conduit 104.

Certain embodiments of board enclosure 102 include a plurality of plate brackets 130, 132 to selectively join retention plate 126 to board enclosure 102. For instance, in some embodiments, one or more lateral plate brackets 130 extend from the cabinet-side face 106 adjacent to a lateral side of heating conduit 104. Lateral plate brackets 130 each define at least one lateral hole 134 for receiving a portion of plate bracket 130. Each lateral hole 134 extends through a respective lateral plate bracket 130 in the lateral direction L′. A corresponding lateral prong 140 extends from retention plate 126, e.g., in the lateral direction L′, and is substantially matched to the lateral hole 134 in size and shape. When assembled, a lateral prong 140 is selectively positioned through a respective lateral hole 134 of each lateral plate bracket 130.

Alternatively, or in addition to, lateral plate brackets 130, optional embodiments include one or more vertical plate brackets 132. For instance, in some embodiments, vertical plate brackets 132 extend from the cabinet-side face 106 adjacent to a top or bottom portion of heating conduit 104. Vertical plate brackets 132 each define at least one vertical hole 136 for receiving a portion of plate bracket 132. Vertical hole 136 extends through a respective vertical plate bracket 132 in the vertical direction V′. A corresponding vertical prong 142 extends from retention plate 126, e.g., in the vertical direction V′, and may be matched to the vertical hole 136 in size and shape. Optionally, vertical prong 142 is configured for slidable engagement with vertical plate bracket 132. Vertical prong 142 may be slidably disposed within vertical hole 136. In such embodiments, retention plate 126 may slide, e.g., in the lateral direction L′, while the vertical prong 142 is positioned through vertical plate bracket 132. Optionally, a vertical prong 142 may be selectively positioned through a respective vertical hole 136 of each vertical plate bracket 132.

In exemplary embodiments, retention plate 126 is configured to attach to board enclosure 102 via two discrete motions. For instance, in some such embodiments, a first vertical motion moves retention plate 126 in the vertical direction V′ along heating conduit 104. A plurality of vertical prongs 142 are positioned through a plurality of respective vertical holes 136. Once vertical prongs 142 are positioned through vertical holes 136, a second lateral motion slides retention plate 126 in the lateral direction L′. As a result of the second lateral motion, a plurality of lateral prongs 140 are positioned through respective lateral holes 134. One or more suitable selective attachment members 146, e.g., screws, bolts, clips, brackets, etc., may be provided to simultaneously engage retention plate 126 and board enclosure 102 to selectively prevent an undesired reverse lateral or vertical motion.

Some embodiments further includes a foam insulation 148 positioned on cabinet 12 between the outer surface 13 of cabinet 12 and the cabinet-side face 106 of board enclosure 102. At least a portion of foam insulation 148 may contact heating conduit 104. Furthermore, foam insulation 148 may extend through the apertures 128 of retention plate 126 between the outer surface 13 and the board enclosure 102. In certain exemplary embodiments, board enclosure 102 is positioned against the foam insulation 148 such that foam insulation 148 substantially covers cabinet-side face 106 without blocking cavity-side face 108. In other words, foam insulation 148 may cover one side of board enclosure 102 while leaving the opposite side uncovered and otherwise accessible.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. An appliance comprising:
a cabinet having an outer surface and an inner surface defining an enclosed chilled chamber;
a board enclosure defining a protective cavity, the board enclosure being attached to the outer surface of the cabinet;
an electronic circuit board attached to the board enclosure within the protective cavity; and
a heating conduit enclosing a circulating fluid, the heating conduit being positioned in conductive heating engagement with a portion of the board enclosure to supply heat to the protective cavity.

2. The appliance of claim 1, wherein the heating conduit is attached to the board enclosure between the chilled chamber and the electronic circuit board.

3. The appliance of claim 2, further comprising a foam insulation positioned on the heating conduit between the outer surface and the board enclosure.

4. The appliance of claim 1, wherein the circulating fluid includes a refrigerant.

5. The appliance of claim 4, further comprising a compressor disposed in fluid communication with the heating conduit and upstream therefrom, the compressor being operable to flow the refrigerant through the heating conduit.

6. The appliance of claim 5, further comprising a condenser disposed in fluid communication with the heating conduit and upstream therefrom, wherein the condenser receives the flow of refrigerant from the compressor before the refrigerant enters the heating conduit.

7. The appliance of claim 6, further comprising a fluid filter disposed in fluid communication with the heating conduit and downstream therefrom, the fluid filter being operable to draw excessive moisture from the refrigerant.

8. The appliance of claim 1, wherein the heating conduit defines a plurality of conduit passes positioned on the board enclosure.

9. The appliance of claim 1, wherein the board enclosure includes a plurality of integral tabs extending from the board enclosure in contact with the heating conduit.

10. The appliance of claim 1, further comprising:
a retention plate positioned across the heating conduit between the outer surface and the heating conduit.

11. The appliance of claim 10, wherein the retention plate defines a plurality of apertures extending through the retention plate.

12. The appliance of claim 11, wherein the heating conduit is attached to the board enclosure between the chilled chamber and the electronic circuit board.

13. The appliance of claim 12, further comprising a foam insulation extending through the apertures of the retention plate between the outer surface and the board enclosure.

14. An appliance comprising:
a cabinet having an outer surface and an inner surface defining an enclosed chilled chamber;
a board enclosure defining a protective cavity, the board enclosure being attached to the outer surface of the cabinet;
an electronic circuit board attached to the board enclosure within the protective cavity; and
a sealed refrigeration loop comprising
a compressor operable to generate a flow of refrigerant,
a condenser disposed downstream of the compressor such that the condenser receives the flow of refrigerant from the compressor during operation of the compressor,
a heating conduit disposed downstream of the condenser in conductive heating engagement with a portion of the board enclosure to supply heat to the protective cavity, and
an expansion device disposed downstream of the heating conduit.

15. The appliance of claim 14, wherein the heating conduit is attached to the board enclosure between the chilled chamber and the electronic circuit board.

16. The appliance of claim 14, wherein the heating conduit defines a plurality of conduit passes positioned on the board enclosure.

17. The appliance of claim 1, further comprising:
a retention plate positioned across the heating conduit between the outer surface and the heating conduit.

18. The appliance of claim 10, wherein the retention plate defines a plurality of apertures extending through the retention plate.

19. The appliance of claim 11, wherein the heating conduit is attached to the board enclosure between the chilled chamber and the electronic circuit board.

20. The appliance of claim 12, further comprising a foam insulation extending through the apertures of the retention plate between the outer surface and the board enclosure.
